(19) United States
(12) Patent Application Publication
(10) Pub. No.: US 2017/0026764 A1
(43) Pub. Date: Jan. 26, 2017

(54) AUTOMATIC CAR AUDIO VOLUME CONTROL TO AID PASSENGER CONVERSATION

(71) Applicant: Panasonic Automotive Systems Company of America, Division of Panasonic Corporation of North America, Peachtree City, GA (US)

(72) Inventor: SHANTHA KUMARI RAJENDRAN, FARMINGTON HILLS, MI (US)

(73) Assignee: Panasonic Automotive Systems Company of America, Division of Panasonic Corporation of North America

(21) Appl. No.: 15/215,521

(22) Filed: Jul. 20, 2016

Related U.S. Application Data
(60) Provisional application No. 62/195,891, filed on Jul. 23, 2015.

(51) Int. Cl. H04R 29/00; H04R 1/08; G10K 11/178; H03G 3/30

(52) U.S. Cl. CPC H04R 29/001; H03G 3/3005; H04R 1/08; G10K 11/178; H04R 2499/13

(57) ABSTRACT

A method of controlling the volume level of an audio signal in a vehicle includes the computer-implemented steps of detecting human speech within a passenger compartment of the vehicle, and automatically adjusting, dependent upon the detecting step, a volume level within the passenger compartment of an audible signal being presented by an audio system of the vehicle.

### CROSS-REFERENCED TO RELATED APPLICATIONS

This application claims benefit of U.S. Provisional Application No. 62/195,891 filed on Jul. 23, 2015, which the disclosure of which is hereby incorporated by reference in its entirety for all purposes.

### FIELD OF THE INVENTION

The disclosure relates to a method of controlling an audio signal in a vehicle, and, more particularly, to a method of controlling the volume of an audio signal in a vehicle.

### BACKGROUND OF THE INVENTION

It is normal that during a long trip passengers listen to loud music but will like to have intermittent conversation among the other passengers. Currently, in order for the passengers to hear each other, a passenger must manually turn down the volume in response to the start of a conversation, and manually turn the volume back up in response to the end of the conversation. More particularly, when a rear seat passenger talks while audio is being played at a high volume, the driver and passenger in the front seat may not hear the rear seat passenger clearly. The driver or front seat passenger may need to reduce the volume manually or the rear seat passenger may need to shout in order to be heard by the other passengers.

### SUMMARY

The present invention may reduce the car audio volume automatically when the passengers and driver inside the car start speaking with each other. The system may monitor for speech and reduce the audio volume level when speech is detected. When the passenger conversation is no longer detected, the audio volume may be automatically increased back to its former pre-conversation volume level. The system may periodically monitor for speech in order to be able to reduce the volume and set the volume back to its former increased level.

A user is able to turn off this automatic volume change feature if he prefers. For example, a user may want to turn off the feature if the passengers are singing along with the song or if the user does not want to listen to what the other passenger is saying.

Currently, such an automatic volume control to help ease passenger communication is not present in any commercial car audio system. Thus, the present invention provides a unique convenience feature for the car users. The car passengers may have to speak louder or reduce audio volume manually with the existing systems. With the inventive system, in contrast, the volume level may be automatically controlled based on detection of the passenger's speech.

In one embodiment, the invention comprises a method of controlling the volume level of an audio signal in a vehicle, including the computer-implemented steps of detecting human speech within a passenger compartment of the vehicle, and automatically adjusting, dependent upon the detecting step, a volume level within the passenger compartment of an audible signal being presented by an audio system of the vehicle.

In another embodiment, the invention comprises a method of controlling an audio signal in a vehicle, including the following computer-implemented steps. An audio signal is played at a first volume level within a passenger compartment of the vehicle. In response to detecting human speech within the passenger compartment of the vehicle, the volume of the audio signal as played within the passenger compartment is reduced to a second volume level that is lower than the first volume level. In response to ascertaining that the human speech within the passenger compartment of the vehicle has ceased, the volume of the audio signal as played within the passenger compartment is increased to a third volume level that is higher than the second volume level.

In yet another embodiment, the invention comprises a motor vehicle including an infotainment arrangement having a loudspeaker emitting first audible sounds within a passenger compartment of the vehicle based on an audio signal received by the loudspeaker. A microphone produces a microphone signal dependent upon the first audible sounds and upon human speech detected within the passenger compartment of the vehicle. A noise cancellation module receives the audio signal and the microphone signal, and removes effects of the audio signal from the microphone signal to thereby transmit a speech signal. A processor receives the speech signal from the noise cancellation module, determines whether the speech signal indicates a presence of human speech, and reduces a volume of the audio signal if the speech signal indicates a presence of human speech.

Automatically reducing the volume of the audio head unit based on recognition of the human conversation helps the inmates of the car communicate clearly without needing to manually reduce the audio volume or talk louder.

The invention may solve the following problems:
1. Passengers in the car not being able to have a clear conversation because of high audio unit volume level.
2. Passengers having to manually reduce the volume level in order for speech to be heard among the passengers.
3. Passengers having to speak louder in order for their voices to be heard by the other passengers amidst the high audio volume.

### BRIEF DESCRIPTION OF THE DRAWINGS

A better understanding of the present invention will be had upon reference to the following description in conjunction with the accompanying drawings.

FIG. 1 is a block diagram of one embodiment of an automatic vehicle audio volume control system of the present invention.

FIG. 2 is a block diagram of another embodiment of an automatic vehicle audio volume control system of the present invention.

FIG. 3 is a flow chart of one example embodiment of an automatic passenger conversation volume control method of the present invention.

FIG. 4 is a flow chart of another example embodiment of an automatic passenger conversation volume control method of the present invention.

### DETAILED DESCRIPTION OF THE PREFERRED EMBODIMENTS

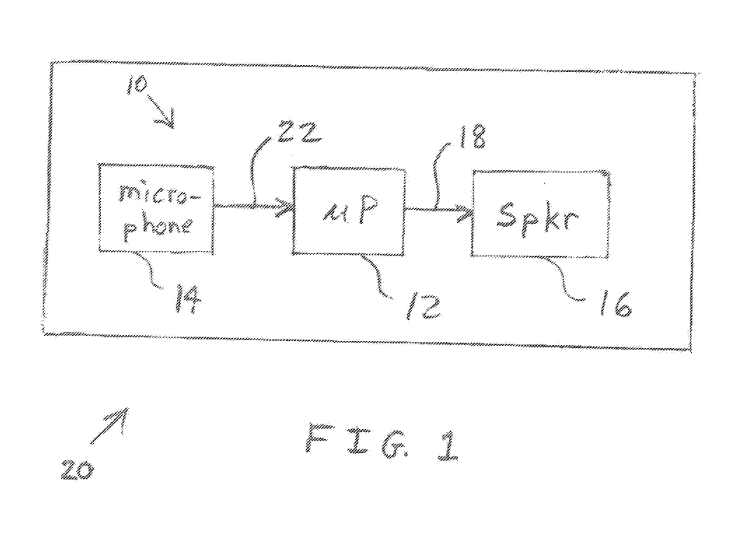

FIG. 1 illustrates one embodiment of an automatic vehicle audio volume control system 10 of the present invention, including a processor 12, a noise cancelled microphone 14, and a loudspeaker 16. During use, processor 12 sends audio signals 18 to loudspeaker 16 to drive speaker 16 and cause sound (e.g., music) to be produced by speaker 16. Microphone 14 may be disposed in the passenger compartment of a vehicle 20 in which system 10 is installed. Microphone 14 detects sound within the passenger compartment and sends a microphone signal 22 based on the detected sounds to processor 12. Processor 12 determines whether signal 22 includes any speech sound that did not originate from speaker 16 and audio signal 18. If so, it is determined that the speech sound originates from a human conversation in the passenger compartment. The conversation may include multiple passengers, or only a single passenger who is talking to the other passengers or talking on a mobile phone. In response to detecting the human conversation, processor 12 may reduce the audio volume of signal 18. When processor 12 determines from subsequent signals 22 that the conversation has ceased, such as after a threshold period of time without human speech, processor 12 may return audio signal 18 to its initial volume level that was in effect before the conversation.

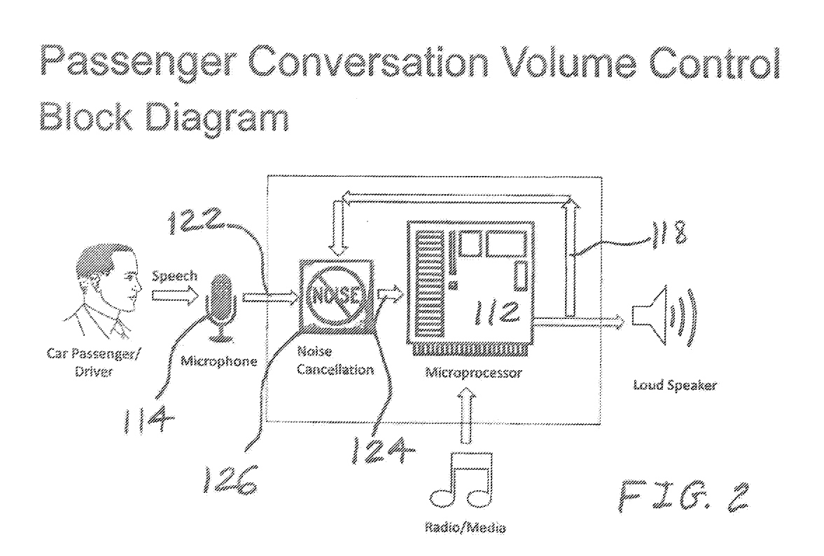

In the more specific embodiment of FIG. 2, a noise cancellation block is shown to cancel audio signal 118 from microphone signal 122. Thus, a noise cancelled signal 124 received by processor 112 may represent only the speech detected by microphone 114.

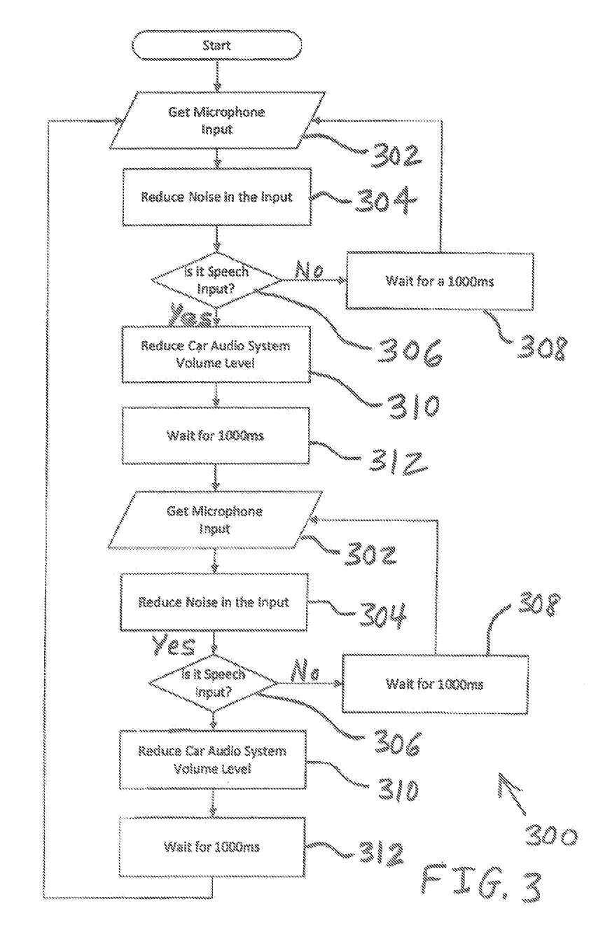

FIG. 3 illustrates an embodiment of a method 300 of the present invention for automatically controlling the volume of a vehicle audio system. In a first step 302, microphone input is obtained. For example, microphone 114 may produce a signal 122 based on sound detected in a vehicle passenger compartment.

Next, in step 304, noise in the input is reduced. That is, noise cancellation module 126 may remove the effects of audio signal 118 from microphone signal 122 to thereby produce noise cancelled speech signal 124.

In a next step 306, it is determined whether the signal is speech input. That is, processor 112 may determine whether signal 124 indicates the presence of any human speech. Processor 112 may analyze the frequencies of signal 124 to make this determination. For example, road noise or engine noise may have different frequencies than human speech. If it is determined that signal 124 does not include speech, then operation proceeds to step 308 where there is one second of waiting time. Operation then goes back to step 302. On the other hand, if it is determined in step 306 that signal 124 does indeed include speech, then operation proceeds to step 310 where the volume level of the car audio system is reduced so that the speech by the passenger may be more easily heard. Next, one second of waiting occurs in step 312, and operation proceeds back to step 302 where the above-described process is cyclically repeated.

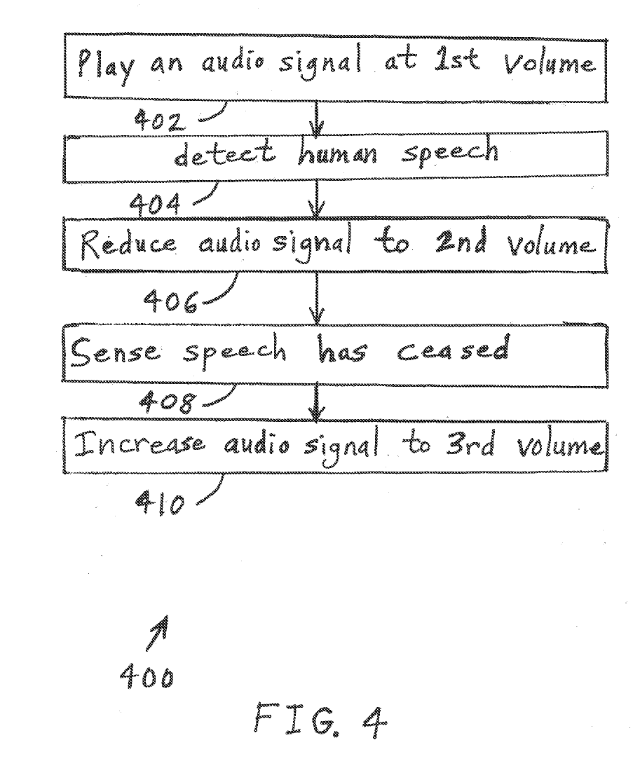

FIG. 4 illustrates another embodiment of a method 400 of the present invention for automatically controlling the volume of a vehicle audio system. In a first step 402, an audio signal is played at a first volume level within a passenger compartment of the vehicle. In a second step 404, human speech is detected within the passenger compartment of the vehicle. For example, microphone signals 22 from microphone 14 may be received by processor 12, and processor 12 may determine that signals 22 are the result of speech based on the frequencies that are present in signals 22. Next, in step 406, in response to the detecting of the speech, the volume of the audio signal as played within the passenger compartment is automatically reduced to a second volume level that is lower than the first volume level. That is, processor 12 may reduce the audio volume of signal 18. In step 408, it is ascertained that the human speech within the passenger compartment of the vehicle has ceased. For example, processor 12 may determine that signals 22 no longer include the frequencies that are characteristic of human speech. In a final step 410, in response to sensing that the speech has stopped, the volume of the audio signal as played within the passenger compartment is increased to a third volume level that is higher than the second volume level. That is, processor 12 may increase the audio volume of signal 18 such that it is played louder than it was while the speech was occurring. The present invention has been described as adjusting audio volume in response to the detection or non-detection of sounds originating from audible speech. However, in other embodiments, the presence of human speech is detected in other ways. In one embodiment, lip movement of the driver and passenger is detected by using a camera, and such lip movement is considered an indication of the presence of speech.

In another embodiment, a command spoken by a user, or the press of a button by a user, is detected and considered an indication of the presence of speech, and thus may trigger a reduction in the audio volume. Although this embodiment may not provide a fully automatic method of reducing and then restoring the volume of the audio system, this embodiment may provide a smart and convenient feature to facilitate clear conversation between the passengers of the car.

The foregoing description may refer to “motor vehicle”, “automobile”, “automotive”, or similar expressions. It is to be understood that these terms are not intended to limit the invention to any particular type of transportation vehicle. Rather, the invention may be applied to any type of transportation vehicle whether traveling by air, water, or ground, such as airplanes, boats, etc.

The foregoing detailed description is given primarily for clearness of understanding and no unnecessary limitations are to be understood therefrom for modifications can be made by those skilled in the art upon reading this disclosure and may be made without departing from the spirit of the invention.

What is claimed is:

1. A method of controlling the volume level of an audio signal in a vehicle, the method comprising the computer-implemented steps of:
detecting human speech within a passenger compartment of the vehicle; and
automatically adjusting, dependent upon the detecting step, a volume level within the passenger compartment of an audible signal being presented by an audio system of the vehicle.

2. The method of claim 1 wherein a microphone is used in detecting the human speech and the audible signal, the detecting including removing effects of the audible signal from a microphone signal produced by the microphone.

3. The method of claim 2, further comprising ascertaining whether the microphone signal includes frequency components within a frequency range of human speech.

4. The method of claim 1 wherein the volume level within the passenger compartment of the audible signal is decreased in response to the detecting of the human speech, and is subsequently increased in response to detecting that the human speech has ceased.

5. The method of claim 4 wherein the volume level within the passenger compartment of the audible signal is increased in response to detecting that the human speech has ceased to about the same volume level that the audible signal was at before the human speech was detected.

6. The method of claim 1 wherein the detecting and adjusting steps are cyclically repeated.

7. The method of claim 1 wherein the detecting and adjusting steps are cyclically repeated with a frequency of greater than once every three seconds.

8. A method of controlling an audio signal in a vehicle, the method comprising the computer-implemented steps of:
playing an audio signal at a first volume level within a passenger compartment of the vehicle;
detecting human speech within the passenger compartment of the vehicle;
in response to the detecting step, reducing the volume of the audio signal as played within the passenger compartment to a second volume level that is lower than the first volume level;
ascertaining that the human speech within the passenger compartment of the vehicle has ceased; and
in response to the ascertaining step, increasing the volume of the audio signal as played within the passenger compartment to a third volume level that is higher than the second volume level.

9. The method of claim 8 wherein the third volume level is approximately equal to the first volume level.

10. The method of claim 8 wherein the ascertaining step includes ascertaining that the human speech within the passenger compartment of the vehicle has ceased for at least a threshold period of time.

11. The method of claim 8 wherein the detecting step occurs while the audio signal is played at the first volume level within the passenger compartment.

12. The method of claim 11 wherein the detecting step includes using a microphone to produce a microphone signal, and removing from the microphone signal effects of the audio signal.

13. The method of claim 12 wherein a noise cancellation module removes the effects of the audio signal from the microphone signal.

14. The method of claim 8 wherein the audio signal is checked for the presence of human speech at least once every three seconds.

15. A motor vehicle, comprising an infotainment arrangement including:
a loudspeaker configured to emit first audible sounds within the passenger compartment based on an audio signal received by the loudspeaker;
a microphone configured to produce a microphone signal dependent upon the first audible sounds and upon human speech detected within a passenger compartment of the vehicle;
a noise cancellation module configured to:
receive the audio signal and the microphone signal; and
remove effects of the audio signal from the microphone signal to thereby transmit a speech signal; and
a processor configured to:
receive the speech signal from the noise cancellation module;
determine whether the speech signal indicates a presence of human speech; and
reduce a volume of the audio signal if the speech signal indicates a presence of human speech.

16. The vehicle of claim 15 wherein the processor is configured to:
ascertain, based on the microphone signal, that the human speech within the passenger compartment of the vehicle has ceased; and
in response to ascertaining the lack of human speech, increase the volume of the audio signal as played within the passenger compartment.

17. The vehicle of claim 16 wherein the processor is configured to, in response to ascertaining the lack of human speech, increase the volume of the audio signal to about the same volume as played within the passenger compartment before the determination of the presence of human speech.

18. The vehicle of claim 16 wherein the processor is configured to ascertain that the human speech within the passenger compartment of the vehicle has ceased for at least a threshold period of time.

19. The vehicle of claim 15 wherein the processor is configured to determine whether the speech signal indicates a presence of human speech about once per second.

20. The vehicle of claim 15 wherein the reduced volume level of the audio signal is dependent upon the volume level of the audio signal before the reduction.

21. The vehicle of claim 15 wherein the reduced volume level is a predetermined percentage of the volume level of the audio signal before the reduction.

22. The vehicle of claim 15 wherein the reduced volume level of the audio signal is independent of the volume level of the audio signal before the reduction.

23. The vehicle of claim 15 wherein the reduced volume level is a predetermined decibel level.
